(19) United States
(12) Patent Application Publication
(10) Pub. No.: US 2016/0381817 A1
(43) Pub. Date: Dec. 29, 2016

(54) Method for Producing an Electronic Module having an Interlockingly Connected Housing Part Element

(71) Applicant: ROBERT BOSCH GMBH, Stuttgart (DE)

(72) Inventors: Harald Ott, Freiberg Am Neckar (DE); Gerhard Wetzel, Korntal-Muenchingen (DE); Gerald Kammer, Ludwigsburg (DE)

(73) Assignee: Robert Bosch GmbH, Stuttgart (DE)

(21) Appl. No.: 15/105,997

(22) PCT Filed: Nov. 4, 2014
(86) PCT No.: PCT/EP2014/073684

§ 371 Date: Jun. 17, 2016

(30) Foreign Application Priority Data
Dec. 17, 2013 (DE) 10 2013 226 150.0

(51) Int. Cl. H05K 5/00; B29C 65/00; B29C 65/14; B29C 65/16; H05K 3/30; H05K 3/00

(52) U.S. Cl. CPC H05K 5/0082; H05K 3/303; H05K 3/0026; B29C 65/1432; B29C 65/1635; B29C 66/712; B29C 66/7212; B29C 66/7392; B29C 66/7394; B29C 66/322; B29L 2031/3481

(57) ABSTRACT

A method for producing an electronic module includes arranging a housing part element on a circuit board element after separately producing and preparing the housing part element. The housing part element is formed with a material that can be reversibly plasticized, such as a thermoplastic like polyamide. At least a portion of a surface of the housing part element is reversibly plasticized, for example via local heating or light irradiation. Arranging the housing part element on the circuit board element includes joining the plasticized portion of the surface of the housing part element to a microstructured portion of the circuit board element and then hardening the plasticized portion to form an interlocking and hermetically sealed connection therebetween.

### FIELD OF THE INVENTION

The present invention relates to a method for producing an electronic module having a circuit board element and a housing subelement applied thereon.

### PRIOR ART

Electronic modules are used in general to form electrical circuits. The electrical circuits may, for example, be part of a control device. Particularly in vehicle construction, electronic modules are used in order to provide vehicle control devices. An electronic module in this case typically contains, on a circuit board element, a multiplicity of electronic components which are electrically connected to one another in a suitable way with the aid of conductive tracks.

Particularly for transmission control devices in a vehicle, it may be advantageous to arrange a corresponding electronic module in a region in which it is exposed to aggressive media. An electronic module of a transmission control device may for example be arranged inside a vehicle gearbox, where for example chemically aggressive gear oil, dirt or splinters may come in contact with the electronic module. Since at least parts of the components, conductive tracks, etc. provided on the electronic module may be sensitive to such aggressive media or particles, it may be necessary to protect them with a hermetically sealed housing.

It has been proposed to fit the circuit board element carrying the electronic components directly as a part of such a housing and to place one or more housing subelements on this circuit board element. A housing subelement may in this case, for example, be a cover or a frame, which form a housing optionally together with other components, and in particular together with the circuit board element. The circuit board element, together with the housing subelement or the housing subelements, may in this case hermetically enclose in a leaktight fashion a space in which electronic components can be accommodated while being protected from ambient media.

For example, it is described in DE 10 2012 213917 A1 to provide a surface of the circuit board element with microstructuring in an annular subregion, and subsequently to mold plastic onto this microstructured subregion so as to form a frame or a cover element. The plastic to be molded on may in this case enter cavities in the microstructured subregion in the initially liquid state and enter into a form-fit connection to the circuit board element during the subsequent solidification.

With such a method for applying a housing subelement on a circuit board element, however, the entire circuit board element must be introduced into an injection-molding tool. During an injection-molding process, the circuit board element and electronic components possibly already applied thereon may in this case become damaged or contaminated.

### DISCLOSURE OF THE INVENTION

According to embodiments of the invention, a method for producing an electronic module is provided, with which it is advantageously possible to avoid introducing a circuit board element into an injection-molding tool. Accordingly, risks of damage or contamination can be minimized.

The method according to the invention for producing an electronic module comprises at least the following steps: providing a circuit board element, having at least one electronic component as well as a microstructured subregion on a surface of the circuit board element, and applying a housing subelement on the circuit board element. The proposed method is characterized in that the step of applying the housing subelement on the circuit board element comprises the following substeps: first, a separately produced housing subelement is provided, the housing subelement being formed with a reversibly plasticizable material. At least one subregion of a surface of this housing subelement is then reversibly plasticized. The housing subelement is then applied on the circuit board element by assembling the plasticized subregion of the surface of the housing subelement with the microstructured subregion of the circuit board element and subsequently solidifying the plasticized subregion of the surface of the housing subelement.

Ideas for the proposed method may, inter alia, be understood on the basis of the concepts and discoveries described below:

Circuit board elements used for electronic modules often consist of a material, for example thermosetting material, for example epoxy resin, which can often be connected by conventional methods to other materials only with the aid of measures by which electronic components on the circuit board element may be damaged. For example, it has previously been possible to adhesively bond a circuit board element produced from a thermoset to other materials only with the aid of heat-treatment steps, in which case electronic components may suffer damage at the high temperatures then occurring. In particular, it has proven very difficult to adhesively bond a thermoset circuit board element to other materials straightforwardly and with little damage in the long term both mechanically stably and in a hermetically sealed way.

It has therefore been proposed to provide the circuit board element in a controlled way with microstructuring at least in subregions. Such microstructuring differs from an otherwise smooth surface of a circuit board element in that the surface has a certain roughness which is due to microscopic indentations in the surface. The microstructuring may, for example, be generated by exposure with a laser, so that parts of the circuit board element are removed by absorption of laser radiation and microscopically small indentations, which form microstructuring, can therefore be created.

Although it has previously been proposed to fasten housing subelements on the circuit board element by molding them directly with the aid of injection-molding elements onto the circuit board element in the region of the microstructured subregions, it has now been discovered that such direct molding may entail manufacturing technology disadvantages. Either the molding process needs to be carried out before the circuit board element is equipped with electronic components, in which case any contamination occurring needs to be removed from the circuit board element after the molding process before the electronic components are applied, or alternatively such electronic components, which have already been applied on the circuit board element before the molding process, need to be protected during the molding, for example by a protective layer, although this requires additional working steps and therefore entails additional costs.

As an alternative to molding housing subelements on, it is therefore proposed here for a housing subelement already to be produced separately beforehand, for example by a separately carried out injection-molding method. The housing subelement should in this case be formed from a reversibly plasticizable material. For example, the housing subelement may be produced from a thermoplastic material, for example polyamide, for example PA66. Such a material should normally be solid and sufficiently mechanically stable for use in an electronic module.

On the other hand, such a material should be reversibly plasticizable, i.e. it can be converted reversibly into a plastic, i.e. viscous or liquid and therefore plastically deformable state, and subsequently resolidified. By the production of such a housing subelement in a separate injection-molding method, the risk of damaging or contaminating the circuit board element or electronic components applied thereon is avoided.

In order to connect the separately produced housing subelement to the circuit board element, at least one subregion of a surface of the housing subelement is reversibly plasticized.

To this end, this subregion may, for example, be temporarily heated locally. By such local heating, at least a layer of the housing subelement near the surface becomes temporarily plasticized, i.e. soft and deformable. In this state, the housing subelement and the circuit board element are assembled. The assembly is carried out in such a way that the plasticized subregion of the surface of the housing subelement is brought in contact with the microstructured subregion of the circuit board element, and the two are as far as possible pressed together. Parts of the material of the housing subelement which have already been plasticized beforehand can in this case flow into indentations or microcavities in the microstructured subregion of the circuit board element. After the previously plasticized material of the housing subelement has been resolidified, for example by cooling, a form-fit connection is therefore formed at least partially between the housing subelement and the circuit board element.

In order to heat the subregion of the surface of the housing subelement temporarily and locally, this subregion may locally be exposed to light, in particular laser light. The applied light should in this case have a sufficiently high power density so that the thermoplastic material of the housing subelement becomes heated to above the plasticizing temperature. A wavelength of the light used should in this case be adapted to material properties of the housing subelement so that the applied light is as far as possible absorbed fully in the region of the housing subelement near the surface, and thereby heats it. For example, a pulsed laser which has a wavelength in the range of from 200 nm to 10 μm, preferably between 512 nm and 1064 nm, and a power of about 1 to 100 watts, may be used for the exposure.

As an alternative, however, it is also conceivable to plasticize, and in particular to heat, the housing subelement surface subregion to be plasticized by means of other techniques. For example, this subregion may be heated by hot air, thermal radiation, contact with a hotplate or another heating object, etc. With most of these alternative approaches, however, in contrast to exposure to light it is not always possible to ensure that the energy for plasticizing the subregion is locally introduced exclusively into the subregion, or that the subregion is contaminated.

The microstructured subregion of the surface of the circuit board element may have indentations with structure dimensions in the range of from 0.1 to 500 μm, preferably between 1 and 100 μm. The plasticized material of the housing subelement can flow well into such indentations or microcavities when the housing subelement is assembled with the circuit board element, be distributed therein, and produce a form-fit connection after subsequent solidification.

Such depressions or microcavities may, in particular, be generated by local exposure with a laser. In this case as well, the wavelength and power density of the laser should be selected suitably, it not being sufficient, however, that the exposure to the laser light merely plasticizes or melts the material of the circuit board element. Rather, the material needs to be locally removed, for example by vaporization or ablation. Accordingly, the laser radiation used for this purpose should generally have a power density higher than is the case merely for plasticizing a thermoplastic material. To this end, for example, a pulsed laser with a wavelength in the range of from 200 nm to 10 μm, preferably between 512 nm and 1064 nm, and a power of about 1 to 100 watts, may be used.

In particular for the use of an electronic module as a transmission control device as described in the introduction, it may be advantageous or necessary not only to connect the housing subelement mechanically firmly to the circuit board element, but also with the aid of this connection to hermetically sealed from the outside an internal volume contained between them. In particular, to this end the housing subelement may have an annularly continuous contact surface, and the housing subelement surface subregion to be plasticized may be this contact surface of the frame. The microstructured subregion of the surface of the circuit board element may likewise be annularly continuous and, in this case, correspond in terms of its geometry to the contact surface of the housing subelement. In this way, the housing subelement and the circuit board element can be assembled with one another along an annularly continuous contact surface, in which case plasticized material of the housing subelement can flow into microstructured material of the circuit board element along the entire contact surface and subsequently solidify therein. This leads to a form-fit connection, which is also hermetically sealed, along the entire annularly continuous contact surface.

It should be pointed out that possible features and advantages of embodiments of the method proposed herein may be combined or replaced in a suitable way in order to obtain further embodiments of the invention.

### BRIEF DESCRIPTION OF THE DRAWINGS

Embodiments of the invention will be described below with reference to the appended drawings; neither the description nor the drawings are to be interpreted as restrictive of the invention.

FIG. 1 shows a perspective view from above of a circuit board element for an electronic module produced according to the invention.

FIG. 2 shows a perspective view from below of a circuit board element for an electronic module produced according to the invention.

FIG. 3 shows an enlarged sectional view along the line A-A in FIG. 1.

FIG. 4 shows an enlarged sectional view along the line B-B in FIG. 2.

FIG. 5 shows an enlarged sectional view of the regions represented in FIGS. 3 and 4, after these have been assembled in the scope of a production method according to the invention.

FIG. 6 shows a sectional view through an electronic module produced according to the invention.

FIG. 7 shows a partial sectional view through a further electronic module produced according to the invention.

The figures are merely schematic and not true to scale.

References which are the same denote features which are the same or have the same effect in the various drawings.

### EMBODIMENTS OF THE INVENTION

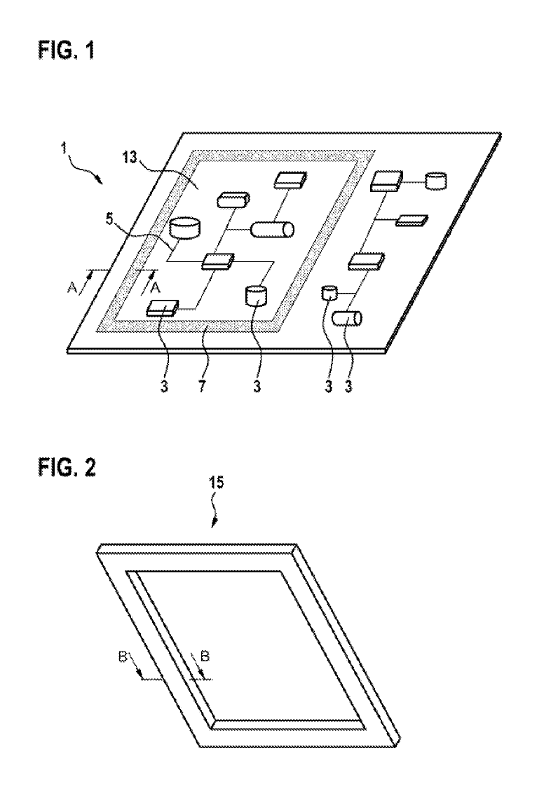

FIG. 1 shows a circuit board element 1 for an electronic module, for example to be used in a transmission control device. The circuit board element 1 has on its surface a plurality of electronic components 3, for example electrical resistors, inductors, capacitors, ICs, etc. The components 3 are connected to one another by electrically conductive tracks 5. The conductive tracks 5 may extend on the surface of the circuit board element 1 or be arranged as intermediate layers inside the circuit board element. The circuit board element 1 consists of thermosetting material, for example epoxy resin, reinforced with glass fibers, sometimes also referred to as a prepreg.

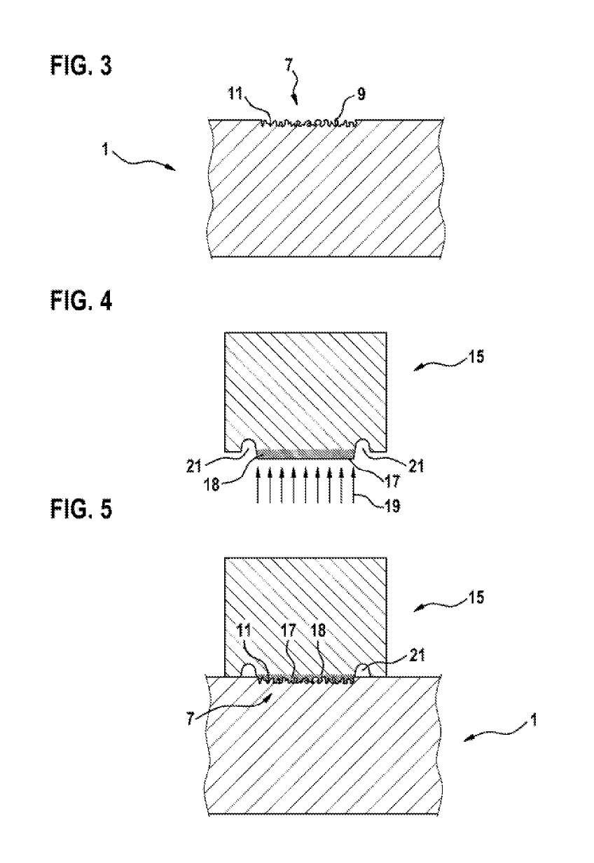

Provided on a surface of the circuit board element 1, there is an annularly continuous subregion 7, in which microstructuring is introduced. FIG. 3 shows this subregion 7, provided with microstructuring 9, in cross section. The microstructuring comprises microscopic indentations 11, which extend for example over a depth of several micrometers into the surface of the circuit board element 1. The microstructured subregion 7 is arranged annularly continuously around a subsurface 13 of the circuit board element 1. Components 3, which for example need to be protected against aggressive media from the surroundings, may be arranged inside this subsurface 13.

FIG. 2 shows a housing subelement 15 in the form of a rectangular frame. The housing subelement 15 consists of a thermoplastic material, for example polyamide. The rectangular shape of the housing subelement 15 in this case corresponds essentially to the shape of the microstructured subregion 7 of the circuit board element 1.

FIG. 4 shows a cross section through the housing subelement 15. In order to temporarily plasticize a subregion 18 next to a contact surface 17 of the housing subelement 15, this contact surface 17 is exposed with the aid of a laser to light 19 with a suitable wavelength and power. The light 19 is in this case absorbed near the surface on the contact surface 17, so that the material there is heated to above its plasticizing temperature, when using polyamide for example to more than 220° C., preferably more than 250° C., and is therefore plasticized. Material overflow recesses or grooves 21 are respectively provided laterally next to the contact surface 17.

FIG. 5 shows a sectional view, in which the parts, which are represented in FIGS. 3 and 4, of the circuit board element 1 on the one hand and of the housing subelement 15 on the other hand have been connected to one another. Plasticized material in that subregion 18 of the housing subelement 15 which is next to the contact surface 17 has in this case flowed into the indentations 11 of the microstructured subregion 7 of the circuit board element 1 and has solidified therein during the subsequent cooling. Excess plasticized material has been partially displaced to the side and can be received in the material overflow grooves 21.

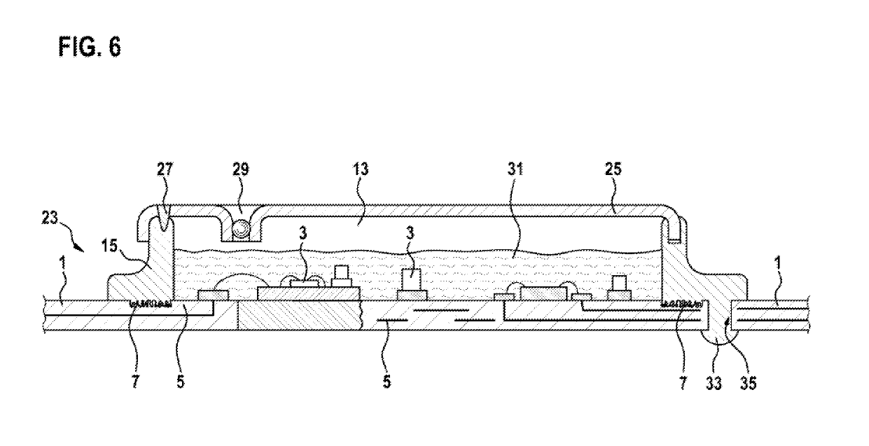

FIG. 6 shows by way of example an electronic module 23 produced according to the invention in cross section. In this case, many optional features, such as may but do not have to be provided on an electronic module, are illustrated. The circuit board element 1 is connected with a form fit by means of the microstructured subregion 7 to the housing subelement 15, configured as a frame. A cover 25 which is connected in a hermetically sealed fashion to the housing subelement 15, for example by means of a weld 27, is placed on the annular frame of the housing subelement 15. The circuit board element 1, the housing subelement 15 and the cover 25 therefore enclose the internal space 13 in a hermetically sealed fashion. The internal space 13 may optionally be filled with a protective gel 31 through an opening 29. The opening 29 may subsequently be closed with the aid of a plug, for example a ball. The housing subelement 15 may in addition be held on the circuit board element 1 by means of at least one rivet head 33. During assembly, the rivet head 33 may be introduced in the undeformed state into an opening 35 in the circuit board element 1 and then hot-caulked.

Although the housing subelement 15 is respectively represented as an annular frame in the examples represented, this housing subelement 15 may also have different shapes and geometries. For example, the housing subelement 15 may be configured as a cover element which has a trough-like shape, so that the internal space 13 is enclosed merely by the housing subelement 15 configured in one piece and the circuit board element 1.

As an alternative, a film, for example of polyamide, which is plasticized in suitable regions and is pressed into microstructured subregions 7 of a circuit board element 1, may be provided as the housing subelement 15. The film may in this case cover the electronic component and protect it from external influences.

Optionally, the film may be coated with a metal layer, which may act as a diffusion barrier or as EMC protection.

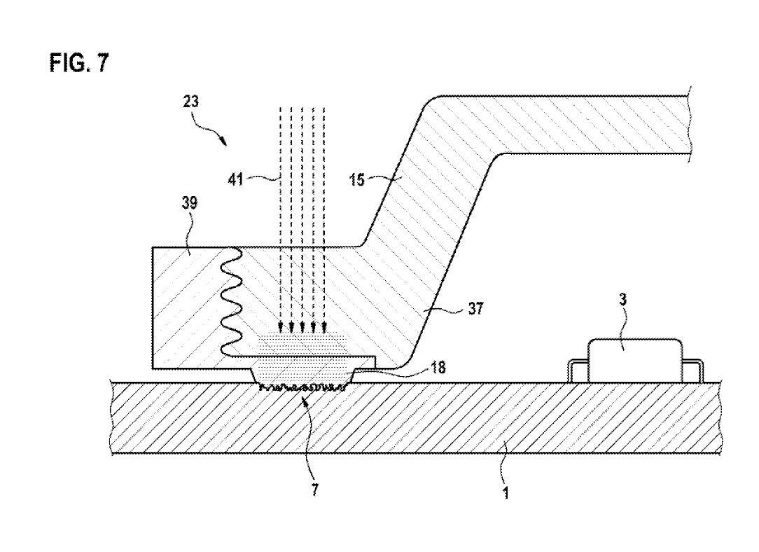

FIG. 7 represents a partial sectional view through a further electronic module 23 produced according to the invention. In this electronic module 23, a cover configured as a housing subelement 15 is configured in two parts. A trough-shaped main part 37 is made of a laser-transparent plastic. An additional part 39, made of a laser-absorbent plastic, is provided at the edge of this main part 37. This additional part 39 encloses the main part 37 annularly and extends into a region in which the microstructured subregion 7 is provided on the circuit board element 1. When the electronic module 23 is being mounted, laser light 41 is transmitted from above through the laser-transparent main part 37 as far as the additional part 39, where it is absorbed. Because of the heat produced by the absorption of the laser light 41, on the one hand the main and additional parts 37, 39 are welded to one another, and on the other hand the plastic of the additional part 39 is plasticized in a subregion 18 to such an extent that it can be connected to the microstructured subregion 7 of the circuit board element 1.

1. A method for producing an electronic module, comprising:
applying a housing subelement on a circuit board element that includes at least one electronic component and a microstructured subregion on a surface of the circuit board element, the housing subelement being an element separately produced from the circuit board element and formed with a reversibly plasticizable material, the applying of the housing subelement on the circuit board element including:
reversibly plasticizing at least one subregion of a surface of the housing subelement;
joining the plasticized subregion of the surface of the housing subelement with the microstructured subregion of the circuit board element; and
subsequent to the joining, solidifying the plasticized subregion of the surface of the housing subelement.

2. The method as claimed in claim 1, wherein reversible plasticizing of the subregion of the surface of the housing subelement includes temporary local heating.

3. The method as claimed in claim 2, wherein the temporary local heating includes local exposure to light.

4. The method as claimed in claim 1, wherein the microstructured subregion of the surface of the circuit board element has indentations with structure dimensions of between 0.1 and 500 μm.

5. The method as claimed in claim 4, further comprising:
generating the indentations in the surface of the circuit board via exposure with a laser.

6. The method as claimed in claim 1, wherein:
the housing subelement defines an annularly continuous contact surface that is adjacent to the at least one subregion of the surface of the housing subelement; and
the microstructured subregion of the surface of the circuit board element is annularly continuous and corresponds to the contact surface of the housing subelement.

7. The method as claimed in claim 1, wherein the housing subelement is formed with a thermoplastic material.

8. The method as claimed in claim 1, wherein the circuit board element is formed with a thermosetting material.

9. The method as claimed in claim 1, wherein the housing subelement is configured as (i) a one-piece cover element or as (ii) a multiple piece element that includes a frame and a separate cover.

10. The method as claimed in claim 1, wherein:
the housing subelement includes a laser-transparent main part and a laser-absorbent additional part; and
the method further comprising applying laser light to weld the main part to the additional part and to plasticize the additional part.

11. The method as claimed in claim 3, wherein the light is laser light.
